(19) United States
(12) Patent Application Publication
(10) Pub. No.: US 2026/0251974 A1
(43) Pub. Date: Aug. 27, 2026

(54) UNDERLAYER AND METHODS FOR EUV DOSE REDUCTION

(71) Applicant: Brewer Science, Inc., Rolla, MO (US)

(72) Inventors: Si Li, Flemington, NJ (US); Kelsey Brakensiek, Rolla, MO (US); Daniel Patrick Sweat, Rolla, MO (US); Joyce A. Lowes, Rosebud, MO (US); Stephen M. Grannemann, Wentzville, MO (US)

(21) Appl. No.: 19/400,290

(22) Filed: Nov. 25, 2025

Related U.S. Application Data
(60) Provisional application No. 63/762,620, filed on Feb. 24, 2025.

(51) Int. Cl. G03F 7/031; G03F 7/00; G03F 7/11

(52) U.S. Cl. CPC G03F 7/031; G03F 7/11; G03F 7/70033

(57) ABSTRACT

Novel lithographic compositions for use as an EUV underlayer are disclosed. The invention includes methods of fabricating microelectronics structures using those compositions as well as structures formed by those methods. The method involves utilizing an underlayer immediately below the photoresist layer, with the underlayer a polymer, oligomer, and/or monomer comprising a cationic moiety. The underlayer can either be directly applied to the substrate, or it can be applied to any intermediate layer(s) that may be applied to the substrate and exhibit uniform thicknesses and low roughness. The disclosed method enables a reduced exposure dose to be utilized while minimizing bridging, scumming, and other pattern defects.

### CROSS-REFERENCE TO RELATED APPLICATIONS

The present application claims the priority benefit of U.S. Provisional Patent Application Ser. No. 63/762,620, filed Feb. 24, 2025, entitled UNDERLAYER AND METHODS FOR EUV DOSE REDUCTION, the entirety of which is incorporated by reference herein.

### BACKGROUND

### Field

This invention relates in general to materials and methods for fabricating microelectronic structures using EUV (extreme ultraviolet) lithography.

### Description of Related Art

As the semiconductor industry continues to follow Moore's law, the demand for ever-decreasing feature sizes requires the use of thinner films to prevent pattern collapse. Extreme ultraviolet (EUV) exposure is expected to be the method of choice for single exposure lithography to achieve the required critical dimension (CD) targets of the 7-nm node and beyond. Unfortunately, EUV lithography has been hindered by problems, including stochastic effects and adhesion issues.

The demands in the semiconductor industry for advanced device manufacturing require materials and processes that enable high resolution, low defectivity, and a stable process window. EUV lithography has been deployed for the sub-20-nm half-pitch feature to achieve higher resolution and lower cost, compared to the multi-patterning immersion ArF. To get even higher resolution, high-numerical-aperture (NA) EUV and multi-patterning EUV lithography are expected to be applied in future nodes. Meanwhile, the development of photoresists suitable for EUV lithography remains critical. Chemically amplified resists (CARs) based on photoacids and organic polymers have been dominant in semiconductor industries for the past decade. However, CARs face challenges in minimizing the line width roughness (LWR), line edge roughness (LER), and resolution at sub-10-nm nodes, due to a large gyration radius of the polymer. The high photon shot noise at low doses in EUV lithography also limits the defect-free resolution of the CARs due to the stochastic effect.

Some efforts to improve the EUV lithography production process have been directed to photoresist improvements. One line of research has led to the development of metal oxide resists (MORs). MORs contain metal oxide complexes in their composition and are designed to absorb EUV photons more efficiently, produce higher contrast, and enable higher resolution than other types of EUV resists. Although MORs are very promising, many issues still hinder achievement of desired EUV lithography manufacturing objectives for pattern quality and throughput.

Recently, organometallic molecules and metal nanoclusters were also developed as alternatives for efficient EUV lithography. The incorporation of metal atoms provides several advantages over traditional organic CARs, like higher EUV absorption, larger quantum yield, smaller resist blur, and better etch resistance. Several commercial MORs have been developed as alternatives for CARs in next-generation nodes. Unlike CARs, which rely on acid diffusion and chemical amplification, MORs operate via a distinct activation and condensation mechanism during EUV exposure, enabling precise pattern formation with reduced variability.

The EUV lithography process is extremely expensive. Thus, any improvements to throughput would be extremely valuable. There are also problems with pattern quality including resolution, LWR, and LER. Underlayers are often used under the photoresist for various reasons, such as to improve adhesion between the resist and the layer on which it is applied. The interactions between an EUV photoresist and any layer immediately underneath it in a lithography stack are complex and varied throughout the lithography process. Efforts to reduce the EUV dose that is required often face a trade-off in that marginally sufficient dose exposure times (to push throughput as high as possible) typically result in resist profiles that are not as straight and clean as desired for advanced (i.e., very small) critical dimensions (CDs).

Spin-on underlayers have traditionally been used along with the CARs to improve sensitivity, LWR, stochastic failure, and process window in the EUV lithography. However, the fundamentally different chemistry of MORs poses unique challenges for underlayer design. This is because smaller organometallic molecules and metal clusters limit the physical entanglement and bonding of the underlayers. Nevertheless, it was noticed that underlayers have a significant impact in MOR EUV lithography regarding the process window, sensitivity, and defects. Spin-on underlayers act as a critical interface between the MOR resist and substrate, which improves resist compatibility, enhances activation, and mitigates defects during patterning.

Thus, despite tremendous efforts there remains a need for underlayers for EUV lithography that improve patterned resist profile while also enabling dose reduction for EUV lithography.

### SUMMARY

In one embodiment, the disclosure provides a method of forming a structure. The method comprises applying a composition to a stack so as to form an underlayer on the stack. The composition comprises a component dissolved or dispersed in a solvent system. The component is chosen from polymers, oligomers, monomers, or a combination thereof. The component also comprises a cationic moiety comprising a ring chosen from heterocyclic rings, multi-heterocyclic rings, or combinations thereof. The ring comprises a positively charged nitrogen ring member, wherein when the ring is

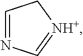

the anion is not

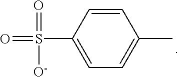

A photoresist layer is formed on said underlayer, and at least a portion of the photoresist layer is subjected to EUV radiation.

In a further embodiment, a structure comprising a substrate having a surface is provided. The substrate surface optionally includes one or more intermediate layers thereon. There is an uppermost intermediate layer on the substrate surface, if one or more intermediate layers are present. An underlayer is on the substrate surface, or on the uppermost intermediate layer, if present. The underlayer comprises an anion from a salt and a component chosen from polymers, oligomers, monomers, or a combination thereof. The component comprises a cationic moiety comprising a ring chosen from heterocyclic rings, multi-heterocyclic rings, or combinations thereof. The ring comprises a positively charged nitrogen ring member; and when the ring is

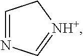

the anion is not

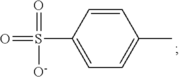

and
A photoresist is on the underlayer.

### BRIEF DESCRIPTION OF THE DRAWINGS

The patent or application file contains at least one drawing executed in color. Copies of this patent or patent application publication with color drawing(s) will be provided by the Office upon request and payment of the necessary fee.

Figure (FIG. 1 is a schematic diagram (not to scale) showing one embodiment of a lithography stack and steps in a lithography process;

FIG. 2 is a focus exposure matrix (FEM) and scanning electron microscope (SEM) image of a sample wafer prepared and tested in Example 2;

FIG. 3 is an FEM of a sample wafer prepared and tested in Example 7;

FIG. 4 is an FEM and an SEM image of a sample wafer prepared and tested in Example 8;

FIG. 5 is an FEM of a sample wafer prepared and tested in Example 9;

FIG. 6 is an FEM of a sample wafer prepared and tested in Example 10;

FIG. 7 is an FEM and an SEM image of a sample wafer prepared and tested in Example 12;

FIG. 8 is an FEM of a sample wafer prepared and tested in Example 14;

FIG. 9 is an FEM of a sample wafer prepared and tested in Example 16;

FIG. 10 is an FEM of a sample wafer prepared and tested in Example 19;

FIG. 11 is an FEM of a sample wafer prepared and tested in Example 21;

FIG. 12 is an FEM of a sample wafer prepared and tested in Example 22;

FIG. 13 is an FEM of a sample wafer prepared and tested in Example 23;

FIG. 14 is an FEM of a sample wafer prepared and tested in Example 27;

FIG. 15 is an FEM of a sample wafer prepared and tested in Example 29;

FIG. 16 is an FEM of a sample wafer prepared and tested in Example 32;

FIG. 17 is an FEM of a sample wafer prepared and tested in Example 34;

FIG. 18 is an FEM of a sample wafer prepared and tested in Example 35;

FIG. 19 is an FEM of a sample wafer prepared and tested in Example 36; and

FIG. 20 is an FEM of a sample wafer prepared and tested in Example 37.

### DETAILED DESCRIPTION

The present disclosure is broadly concerned with compositions for forming underlayers and methods of using those compositions to form microelectronic structures.

### Compositions for Underlayer

Suitable compositions generally comprise one or more components dispersed or dissolved in a solvent system. Broadly, the component comprises a polymer, oligomer, and/or monomer comprising a salt. The salt (through its cationic portion) can be bonded to the polymer, oligomer, and/or monomer, typically as a functional group or part of a side chain in the case of a polymer and/or oligomer. Additionally or alternatively, the salt can be part of the polymer and/or oligomer backbone.

Examples of suitable monomeric compounds include those chosen from the following, along with oligomers and/or polymers (including copolymers and/or blends) thereof: tetraethoxysilane, methyltrimethoxysilane, isobutyltrimethoxysilane, phenyltrimethoxysilane, 2-(3,4-epoxycyclohexyl)-ethyltrimethoxysilane, 3-triethoxysilylpropylsuccinic anhydride, 3-iodopropyltrimethoxysilane, triethoxy-3-(2-imidazolin-1-yl)propylsilane (IMIDTEOS), dimethylaminopropyltrimethoxysilane (DMAPTMS), glycidylPOSS, (3-glycidyloxypropyl) trimethoxysilane (glyTMS), 2-(3,4-epoxycyclohexyl)ethyltrimethoxysilane (ECHTMS), triphydroxysilylethylphenylsulphonic acid (THSPSA), 5,6-epoxyhexyltriethoxysilane (EPOTEOS), triethoxysilylpropylethylcarbamate (TEOSPEC), n-(3-triethoxysilylpropyl)-4-hydroxybutyramide (HATEOS), triethoxysilylpropylsuccinicanhydride (TEOSPSA), 2-(carbomethoxy)ethyltrimethoxysilane (CarboTMS), vinyl trimethoxysilane (VTMS), 3-(trihydroxysilyl)-1-propanesulfonic acid (THSSA), (3-glycidoxypropyl)methyldiethoxysilane (GlyDEOS), methacrylamidopropyltriethoxysilane, aminopropyltriethoxysilane, 3-aminopropyl(diethoxy)methylsilane (APDEOS), or combinations thereof.

In some embodiments, suitable polymers also include carbon-rich polymers, such as those chosen from polystyrene, functionalized polystyrene derivatives (e.g., poly(4-methylstyrene), poly(vinyl naphthalene)), polysulfones, polyethersulfones, poly(ether ether ketone), polycarbonates, epoxies, novolacs, polyimides, 1-(3-sulfopropyl)-2-vinylpyridinium hydroxide, or combinations thereof.

In some embodiments, suitable polymers and/or oligomers for use as the component comprise monomers chosen from phenolic compounds, styrene, styrene-containing compounds, glycidyl-containing compounds, 2-hydroxyethyl methacrylate, hydroxypropyl methacrylate, hydroxybutylacrylate, silanes, siloxanes, or combinations thereof.

In the same or different embodiments, the component can be a monomeric compound, such as those chosen from phenolic compounds, styrene, styrene-containing compounds, glycidyl-containing compounds, 2-hydroxyethyl methacrylate, hydroxypropyl methacrylate, hydroxybutylacrylate, silanes (e.g., 2-(3,4-epoxycyclohexyl)ethyltrimethoxysilane), or combinations thereof.

Suitable cationic moieties bonded with the polymer, oligomer, and/or monomer such as those listed above comprise a heterocyclic ring and/or a multi-heterocyclic ring, with that ring including at least one nitrogen ring member. In some embodiments, the ring comprises two nitrogen atoms as ring members. Preferably, a nitrogen atom of the ring carries the positive charge. Suitable rings can be aromatic or non-aromatic, and the ring can be a 5- or a 6-membered ring. In some embodiments, the cationic moiety comprises a multicyclic structure, preferably comprised of two or more 5- and/or 6-membered rings. One or more nitrogen atoms of the ring can be substituted in some embodiments. Exemplary substitutions include substituted and unsubstituted alkyls (C₁ to about C₆, and preferably C₁ to about C₃), substituted and unsubstituted alkenyls (C₁ to about C₆, and preferably C₁ to about C₃), or combinations thereof. Examples of rings for use as the cationic portion of the salt include substituted and unsubstituted rings chosen from imidazoles (e.g., 1-vinylimidazole), pyridines, pyrimidines, pyrazines, pyridazines, purines, acridines, quinolines, isoquinolines, benzimidazoles, bi-pyridines, phenanthrenes, and/or combinations of the foregoing.

Suitable rings can include substitutions on one or more carbon atoms, with exemplary substitutions including those chosen from substituted and unsubstituted alkyls (preferably C₁ to about C₁₂, more preferably C₁ to about C₆, and even more preferably C₁ to about C₃), substituted and unsubstituted alkenyls (preferably C₁ to about C₁₂, more preferably C₁ to about C₆, and even more preferably C₁ to about C₃), or combinations thereof. In one or more embodiments, one or more carbon ring members are substituted with a vinyl group.

The anion from the salt will depend on the particular reactants, discussed in more detail below, but in some instances, the anion is chosen from halogen anions (e.g., iodide, fluoride, chloride, bromide), hexafluorophosphate, tetrafluoroborate, tetrakis(pentafluorophenyl)borate, or combinations thereof. In some embodiments, the salt bound to the polymer is an external salt. In other embodiments, the salt bound to the polymer is an inner salt, in which case the anion will be bonded to the cation on the polymer, oligomer, and/or monomer.

In the same or other embodiments, the anion comprises a moiety chosen from alkyl sulfonates, alkyl phosphates, or combinations thereof. Suitable alkyl sulfonates have the structure

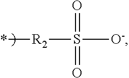

where R₂ is chosen from substituted and unsubstituted alkyls (preferably C₁ to about C₁₂, more preferably C₃ to about C₁₀, and even more preferably C₃ to about C₆), and “*” designates the location of the bond to the cationic portion of the inner salt. In preferred embodiments, R₂ is bonded to a nitrogen atom on the previously described ring of the cationic portion of the salt, and preferably to a nitrogen atom carrying a positive charge.

In some embodiments, when the ring of the cation is

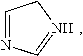

the anion is not

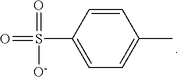

In some embodiments, the salt from which the cation and anion are derived is not triphenylsulfonium nitrate.

A suitable method of forming the above-described components involves an alkylation-type reaction, preferably using a halide. In some instances, the halide is part of the monomer, and that monomer can be used in the compositions and/or that monomer can be used to form an oligomer and/or polymer in oligomeric or polymeric embodiments. Examples of such halide-containing monomers include 3-iodopropyltrimethoxysilane, 3-dimethylaminopropyltrimethoxysilane and triethoxy-3-(2-imidazolin-1-yl)propylsilane (IMIDTEOS), or combinations thereof.

When the halide is part of the monomer, the component can be formed by reacting a compound comprising a ring structure as described above with the halide-containing monomer, oligomer, and/or polymer following conventional methods so as to form the component comprising a cationic moiety. Examples of suitable such ring-containing compounds include those chosen from imidazoles (e.g., 1-vinylimidazole, 1-methylimidazole, 2-methylimidazole, benzimidazole), pyridines, pyrimidines, purines, pyrazolines, phenanthrenes, 1,4-diazabicyclooctane (DABCO), or combinations thereof.

In some embodiments, the monomer, oligomer, and/or polymer may already contain a ring as described above. In these instances, it is preferred to carry out the alkylation-type reaction with a halide, such as an alkyl halide. Suitable halides are chosen from iodine, fluorine, chlorine, bromine, or combinations thereof. Suitable alkyl halides include C₁ to about C₁₄, preferably C₂ to about C₁₀, and more preferably C₂ to about C₈ alkyl halides. Preferred alkyl halides are chosen from iodoethane, iodomethane, 1,8-diiodooctane, 1,5-diiodopentane, or combinations thereof.

In some embodiments, it is desirable to carry out the alkylation-type reaction during oligomerization and/or polymerization, which can be carried out according to known oligomerization and/or polymerization methods (e.g., free radical polymerization). In some instances, polymer can be purchased commercially.

In embodiments where an oligomer or polymer is utilized, the weight-average molecular weight (Mw) range (as measured by gel permeation chromatography) is typically about 500 g/mol to about 150,000 g/mol, preferably about 1,000 g/mol to about 80,000 g/mol, and more preferably from about 2,000 g/mol to about 25,000 g/mol.

Additionally or alternatively, about 50% or more, preferably about 75% or more, more preferably about 90% or more, and even more preferably about 100% of the monomers of the oligomer or polymer will comprise a cationic moiety as described herein. In one or more embodiments, the ratio of cation to anion will be about 0.9:1.1, preferably about 0.95:1.05, and more preferably about 1:1.

In some embodiments where an oligomer or polymer is utilized, the component is a homo-oligomer or homopolymer.

In one or more embodiments, the component (total polymeric, oligomeric, and monomeric) will be present in the composition at levels of about 0.05% by weight to about 20% by weight, preferably about 0.05% to about 10%, and more preferably about 0.1% by weight to about 5% by weight, based upon the total weight of the composition taken as 100% by weight.

Regardless of the particular component (polymeric, oligomeric, and/or monomeric) selected, the underlayer compositions for use herein are formed by mixing the component in a solvent system under ambient conditions until a dispersion or solution is formed. The component will typically be present in the underlayer composition at levels of about 30% by weight to about 99% by weight, preferably about 40% by weight to about 98% by weight, and more preferably about 50% by weight to about 95% by weight, based upon the total weight of the solids in the composition taken as 100% by weight.

Exemplary solvent systems include one or more solvents chosen from propylene glycol methyl ether acetate (PGMEA), propylene glycol methyl ether (PGME), propylene glycol ethyl ether (PGEE), propylene glycol n-propyl ether (PnP), ethyl lactate, cyclopentanone, cyclohexanone, gamma-butyrolactone (GBL), methyl isobutyl carbinol, 3-methyl-1,5-pentanediol, 1,2-propylene glycol, 1,3-propylene glycol, ethylene glycol, water, or mixtures thereof. Preferably, the solvent system has a boiling point of about 70° to about 200° C., and more preferably about 100° to about 150° C.

In some embodiments, the solvent system is preferably utilized at a level of about 98% to about 99.99% by weight, more preferably about 99% to 99.9%, and even more preferably about 99.3% to about 99.8% by weight, based upon the total weight of the composition taken as 100% by weight. In other embodiments, the solvent system is utilized at a level of about 20% to about 99.99% by weight, preferably about 80% to 99.9%, and more preferably about 90% to about 99.9% by weight, based upon the total weight of the composition taken as 100% by weight.

In some embodiment, the compositions used to form the underlayer preferably comprise a solids content of about 0.1% to about 2% by weight solids, more preferably about 0.1% to about 1% by weight solids, and even more preferably about 0.1% to about 0.5% by weight solids, based upon the total weight of the composition taken as 100% by weight. In other embodiments, the compositions used to form the underlayer preferably comprise a solids content of about 0.01% to about 20% by weight solids, preferably about 0.01% to about 10% by weight solids, and more preferably about 0.05% to about 1.5% by weight solids, based upon the total weight of the composition taken as 100% by weight.

A number of optional ingredients could be included in the underlayer composition, and those ingredients would simply be mixed with the solvent system at the same time as the component. For example, in embodiments a crosslinker can be included, with preferred crosslinkers being selected from the group consisting of aminoplasts (e.g., those sold under the name Powderlink® or Cymel® 1170 or Cymel® 303), epoxies (e.g., those sold under the name Araldite® MY720 tetra functional epoxy resin from Huntsman Advanced Materials), and mixtures thereof. When used, the crosslinker is preferably present in the composition at a level of about 5% to about 50% by weight, and preferably about 15% to about 35% by weight, based upon the total weight of the solids in the composition taken as 100% by weight.

In other embodiments, the underlayer composition is substantially free of any crosslinkers. That is, the underlayer composition will comprise less than about 0.001% by weight crosslinker, and preferably about 0% by weight crosslinker, based upon the total weight of the solids in the composition taken as 100% by weight.

In some embodiments, a catalyst (e.g., for crosslinking) is used. Preferred catalysts include, but are not limited to, those selected from the group consisting of 5-sulfosalycilic acid, TAG-2689, CXC-1821, sulfonic acids (e.g., p-toluenesulfonic acid, 5-sulfosalicylic acid), sulfonates (e.g., pyridinium p-toluenesulfonate, pyridinium 3-trifluoromethanesulfonate, pyridinium nitrobenzensulfonate), and combinations thereof. Other thermal acid generators can also be used. When utilized, the catalyst is typically present in the underlayer composition at a level of about 0.1% to about 10% by weight, and preferably about 1% to about 5% by weight, based upon the total weight of the solids in the composition taken as 100% by weight.

In other embodiments, the underlayer composition is substantially free of any catalysts. That is, the underlayer composition will comprise less than about 0.001% by weight catalyst, and preferably about 0% by weight catalyst, based upon the total weight of the solids in the composition taken as 100% by weight.

In some embodiments, a photoacid generator (PAG) is used. Preferably, the PAG is not attached to the polymer, oligomer, or monomer, but instead is simply mixed into the underlayer composition. Preferred PAGs include, but are not limited to, those selected from the group consisting of: onium salts (e.g., triphenyl sulfonium perfluorosulfonates such as TPS nonaflate, TPS triflate, and substituted forms thereof, such as tris(4-tert-butylphenyl) sulfonium perfluoro-1-butanesulfonate (an alkyl-substituted TPS nonaflate); oxime-sulfonates (e.g., those sold under the name CGI® by CIBA); triazines (e.g., TAZ-108® available from Midori Kagaku Company); and combinations thereof. When utilized, the PAG is typically included in the compositions at a level of about 0.001% to about 3% by weight, based upon the total weight of the solids in the composition taken as 100% by weight.

In other embodiments, the underlayer composition is substantially free of any acid generator such as a PAG. That is, the underlayer composition will comprise less than about 0.001% by weight acid generator, and preferably about 0% by weight acid generator, based upon the total weight of the solids in the composition taken as 100% by weight.

In some embodiments, an additive is used. Preferably, the additive is simply mixed into the underlayer composition. Preferred additives include, but are not limited to, those selected from the group consisting of 1,1,1-tris(4-hydroxyphenyl)ethane (THPE), surfactants, and combinations thereof. When included, the additive is typically present in the composition at a level of about 0.001% to about 0.1% by weight, and preferably about 0.01% to about 0.05% by weight, based upon the total weight of the solids in the composition taken as 100% by weight.

In some embodiments, the composition consists essentially of, or even consists of, the component (polymeric, oligomeric, and/or monomeric), dissolved or dispersed in the solvent system.

In other embodiments, the composition consists essentially of, or even consists of, the component (polymeric, oligomeric, and/or monomeric), dissolved or dispersed in the solvent system, along with one, two, or three of a crosslinking agent, a catalyst (acid generator or otherwise), and/or an additive (THPE and/or surfactants).

### Methods of Using the Compositions to Form EUV Underlayer

Referring to FIG. 1(A), a stack 10 is schematically depicted. Stack 10 comprises a substrate 12 having a surface 14 and optional intermediate layer(s) 16.

Substrate 12 comprises a microelectronic substrate, which is typically a semiconductor substrate. Exemplary substrates 12 comprise silicon, SiGe, SiO₂, Si₃N₄, SiON, SiCO:H (such as that sold under the name Black Diamond, by SVM, Santa Clara, CA, US), tetramethyl silate and tetramethyl-cyclotetrasiloxane combinations (such as that sold under the name CORAL), aluminum, tungsten, tungsten silicide, gallium arsenide, germanium, tantalum, tantalum nitride, Ti₃N₄, hafnium, HfO₂, ruthenium, indium phosphide, glass, or combinations of the foregoing. Surface 14 of substrate 12 can be planar, or it can include topographic features (e.g., via holes, trenches, contact holes, raised features, lines, etc.). As used herein, “topography” refers to the height or depth of a structure in or on substrate surface 14. In FIG. 1(A) the surface 14 is illustrated as having a substantially planar topography, but the topography could include non-planar topographies, such as those including lines, trenches, holes, pillars, etc.

FIG. 1 shows a single intermediate layer 16 for illustration purposes, however, the stack 10 can include multiple intermediate layers or no intermediate layers. In some embodiments, a suitable intermediate layer 16 includes a primer layer, which can include a separate and distinct layer or a layer that is more appropriately characterized as a modification of substrate surface 14. Preferred primers include hexamethyldisilizane (“HMDS”). A primer can be formed, for example, by exposing the substrate 12 to a vapor of a primer composition in a sealed chamber while heating at about 150° C. for about 90 seconds.

Another suitable intermediate layer 16 comprises a carbon-rich layer that may be formed on substrate surface 14, or on any other intermediate layer that may be present (e.g., the primed layer or modified surface as discussed above). Carbon-rich layers include, but are not limited to, spin-on carbon (SOC) layers, amorphous carbon layers, and carbon planarizing layers. Exemplary carbon-rich layers are generally formed from a carbon-rich composition comprising a polymer dissolved or dispersed in a solvent(s), along with one or more optional ingredients, including those chosen from acid quenchers, base quenchers, catalysts, crosslinking agents, surface modification additives, or mixtures thereof. Preferred carbon-rich compositions will be capable of being formed into relatively thick layers and thus typically have a solids content of about 0.1% to about 70% by weight, more preferably about 5% to about 40% by weight, and even more preferably about 10% to about 30% by weight, based upon the total weight of the carbon-rich composition taken as 100% by weight. The term “carbon-rich” refers to compositions and/or layers comprising greater than about 50% by weight carbon, preferably greater than about 70% by weight carbon, more preferably from about 75% to about 95% by weight carbon, and even more preferably about 75% to about 90% by weight carbon, based upon the total solids in the composition or layer taken as 100% by weight.

The carbon-rich layer can be formed by any known application method, with one preferred method being spin-coating at speeds of about 1,000 to about 5,000 rpm, and preferably about 1,250 to about 1,750 rpm, for a time period of about 30 to about 120 seconds, preferably about 45 to about 75 seconds. After the carbon-rich composition is applied, it is preferably heated to a temperature of about 100° C. to about 400° C., and more preferably about 160° C. to about 350° C., for a time period of about 30 seconds to about 120 seconds, and preferably about 45 seconds to about 60 seconds, to evaporate solvents. The average thickness of the carbon-rich layer after baking is typically about 5 nm to about 1,000 nm, preferably about 5 nm to about 200 nm, more preferably about 5 nm to about 120 nm, even more preferably about 5 nm to about 100 nm, and most preferably about 10 nm to about 60 nm. As used herein, “average thickness” is determined using an ellipsometer and taking the average of five measurements at five different locations. The carbon-rich layer preferably has an etch rate in oxygen-rich plasma that is at least about 5 times faster than the etch rate of the resist in the same plasma. The carbon-rich layer may also be formed by other conventional application methods, including chemical vapor deposition (“CVD”), plasma-enhanced chemical vapor deposition (“PECVD”), atomic layer deposition (“ALD”), or plasma-enhanced atomic layer deposition (“PEALD”).

An optional hardmask layer may be applied adjacent to the carbon-rich material, to the substrate surface 14, or any intermediate layers on the substrate surface 14. The hardmask layer can be formed by any known application method, such as CVD or PECVD. Another preferred method is spin-coating at speeds of about 1,000 to about 5,000 rpm, and preferably about 1,250 to about 1,750 rpm, for a time period of about 30 to about 120 seconds, and preferably about 45 to about 75 seconds.

Suitable hardmask layers are preferably high-silicon-content materials such as those selected from the group consisting of silanes, siloxanes, silsesquioxanes, silicon oxynitride, silicon nitride, polysilicon, amorphous silicon, or mixtures thereof, or any layer with a high etch bias relative to the underlying layers. Suitable hardmask layers generally compromise a polymer dissolved or dispersed in a solvent system, along with one or more of the following optional ingredients: surfactants, acid or base catalysts, and crosslinkers.

Preferred compositions for forming a hardmask layer preferably have a solids content of about 0.1% to about 70% by weight, more preferably about 0.5% to about 10% by weight, even more preferably about 0.5% to about 2% by weight, and most preferably about 0.5% to about 1% by weight, based upon the total weight of the hardmask composition taken as 100% by weight. After the hardmask is applied, it is preferably heated at a temperature of about 100° C. to about 300° C., and more preferably about 150° C. to about 250° C., for a time period of about 30 seconds to about 120 seconds, and preferably about 45 seconds to about 60 seconds, to evaporate solvents. The average thickness of the hardmask layer after baking is preferably about 5 nm to about 5,000 nm, more preferably about 5 nm to about 1,000 nm, even more preferably about 5 nm to about 100 nm, and most preferably about 10 nm to about 30 nm. The hardmask layer preferably has an etch rate that is about 0.75 times or higher than that of the photoresist in a fluorine-rich plasma atmosphere. Additionally or alternatively, the hardmask layer etch rate is preferably about 20% or less (i.e., five times slower) than that of the carbon-rich layer in an oxygen-rich plasma etch atmosphere.

Commercial hardmask layers can be used. For example, materials commercially available from Brewer Science, Inc. (Rolla, MO) under the tradenames OptiStack® HM710 and OptiStack® HM825 can be used to form suitable hardmasks. Other suitable hardmask layers contain a copolymer of monomers selected from the group containing phenethyltrimethoxysilane, 2-(carbomethoxy)ethyltrimethoxysilane, tetraethoxysilane, methyltrimethoxysilane, methyltrimethoxysilane, ethyltrimethoxysilane, (3-phenyltrimethoxysilane, glycidyoxypropyl)triethoxysilane, 2-(3,4-epoxycyclohexyl)ethyltrimethyoxysilane, or combinations thereof.

Especially preferred silicon hardmasks have a lower carbon content, preferably less than about 30% carbon, more preferably less than about 25% carbon, and even more preferably less than about 20% carbon, all by weight on a solids basis. The silicon hardmask preferably has a higher silicon content, preferably at least about 25% silicon, more preferably at least about 30% silicon, and even more preferably at least about 40% silicon, all by weight on a solids basis.

Regardless of whether zero, one, two, or more intermediate layers are included in stack 10, an underlayer composition as previously described is used to form an underlayer 18 (FIG. 1(B)). Underlayer 18 can be formed directly on the substrate surface 14 if no intermediate layer is utilized (not shown), on the intermediate layer 16 if only one intermediate layer is utilized (as in FIG. 1B, e.g., a carbon-rich layer), or on the intermediate layer that is positioned furthest from substrate surface 14 (i.e., the uppermost intermediate layer, which is preferably a hardmask layer) in embodiments where multiple intermediate layers are included (not shown).

One preferred application method involves spin-coating the underlayer composition at speeds of about 1,000 rpm to about 5,000 rpm, and preferably about 1,250 rpm to about 1,750 rpm, for a time period of about 30 seconds to about 120 seconds, and preferably about 45 seconds to about 75 seconds. After the underlayer composition is applied to form underlayer 18, underlayer 18 is preferably heated at a temperature sufficiently high to evaporate substantially all (about 95% or more) and preferably all (about 100%) of the solvent present in underlayer 18. Suitable baking conditions typically involve temperatures of about 100° C. to about 300° C., and more preferably about 150° C. to about 250° C., for about 30 seconds to about 120 seconds, and preferably about 45 seconds to about 60 seconds.

In some embodiments, the previously described polymer, oligomer, and/or monomer with cationic moiety of the underlayer composition will crosslink during baking, thus forming a crosslinked polymer, oligomer, and/or monomer network, and the anion from the salt will preferably be dispersed, distributed, and/or interspersed within that crosslinked network within formed underlayer 18, preferably in a substantially homogeneous manner.

In some embodiments, some or all of the polymer, oligomer, and/or monomer with cationic moiety will bond with the layer immediately below underlayer 18, with the anion from the salt preferably being dispersed, distributed, and/or interspersed within or among the polymer, oligomer, and/or monomer with cationic moiety.

In even further embodiments, both crosslinking of the polymer, oligomer, and/or monomer with cationic moiety and bonding with the layer immediately below underlayer 18 will take place, again with the anion from the salt being dispersed, distributed, and/or interspersed within or among the crosslinked and/or uncrosslinked polymer, oligomer, and/or monomer with cationic moiety.

In some embodiments, the solvent is evaporated during baking as mentioned above, but the previously described polymer, oligomer, and/or monomer do not crosslink during baking. In these instances, the anion from the salt is dispersed or distributed within the (uncrosslinked) polymer, oligomer, and/or monomer within the formed underlayer 18, preferably in a substantially homogeneous manner.

The average thickness of the underlayer 18 after baking is less than about 20 nm, preferably about 0.5 nm to 20 nm, more preferably about 1 nm to about 15 nm, and even more preferably about 2 nm to about 10 nm.

In some embodiments, the underlayer 18 has a low metal content. That is, the metal content is less than about 0.005% by weight, preferably less than about 0.001% by weight, and more preferably about 0% by weight, based upon the total weight of the underlayer 18 taken as 100% by weight. It is also preferred that the underlayer 18 is non-conducting.

It will be appreciated that the desired contact angle when a drop of water is placed on the underlayer 18 depends on the application. The surface contact angle of underlayer 18 can be determined by averaging 5 measurements taken in different spots using VCA-3000S Wafer System (AST Products, Billerica, MA) contact angle measurement tool, with water as the droplet solvent. In some embodiments, the contact angle of the underlayer 18 after baking is preferably about 40° to about 75°, and more preferably about 50° to about 65°.

It is preferred that the underlayer 18 is substantially non-developable using (i.e., substantially insoluble in) typical organic solvents such as ethyl lactate, propylene glycol methyl ether acetate, propylene glycol methyl ether, propylene glycol n-propyl ether, cyclohexanone, acetone, gamma butyrolactone, or mixtures thereof. Thus, when subjected to a stripping test, the formed underlayer 18 preferably has a percent stripping of less than about 5%, more preferably less than about 1%, and even more preferably about 0%.

The percent stripping can be determined by measuring the average contact angle and average thickness (each determined by averaging measurements taken at five different locations) of the underlayer 18 before the underlayer 18 is exposed to any developer solvents. These averaged measurements are the initial film contact angle and initial film thickness. Next, a solvent (e.g., ethyl lactate) is puddled onto the film for about 30 seconds, followed by spin drying at about 3,000 rpm for about 30 seconds to remove the solvent. The average contact angle and average thickness are each determined again by measuring at approximately the same five locations on the wafer as the locations used to determine the initial film contact angle and initial film thickness, and the averages of these measurements are the final film contact angle and the final film thickness, respectively. The amount of stripping is the difference between the initial and final film thicknesses. The percent stripping is:

$$\% stripping = ( \frac{amount of stripping}{initial average film thickness} ) \times 100$$

In some embodiments, the underlayer 18 is crosslinked. For example, the underlayer 18 is preferably sufficiently crosslinked that % stripping is less than about 30%, more preferably less than about 20%, and even more preferably less than about 10%. One advantage of the crosslinked nature of the underlayer 18 is that there is very little to no unbound polymeric, oligomeric, or monomeric compound in the underlayer 18 after it is baked. This minimal or lack of unbound compound will likely eliminate the need to strip unbound compounds during the semiconductor device manufacturing process, thereby reducing the number of steps and increasing throughput. In one embodiment, there is no solvent or developer rinse step required prior to the application of the photoresist.

In one embodiment, solvent resistance to methyl isobutyl carbinol (MIBC) may be evaluated by stripping test by puddling ~6 mL of solvent on the baked underlayer for 30 seconds followed by 30 seconds of spin-drying at 1500 rpm. Preferably, the MIBC strip will be from about-15% to about 5%, more preferably from about-10% to about 0%, where negative stripping values indicate swelling. Developer resistance may be evaluated via the developer stripping by puddling ~6 mL of developer (Inpria Corporation) on the baked underlayer for 60 seconds followed by 60 seconds of spin-drying at 1500 rpm.

In addition to the strip test, there are additional indications of a high degree of crosslinking of the underlayer 18. Preferably, there are substantially no changes in the water contact angle after contact with solvent or developer, that is, the change in contact angle is preferably less than about 5°, more preferably less than about 3°.

Another indicator of sufficient crosslinking is good thickness uniformity and a substantially uniform and defect-free surface as measured on a KLA SP5. Preferably, the underlayer 18 will have sublimation of less than about 200 ng, more preferably less than about 100 ng, and even more preferably less than about 50 ng when measured with a quartz crystal microbalance (QCM) when heated to about 205° C. for about 3 minutes. A well-crosslinked underlayer 18 will generally have a surface roughness (R1) as measured with atomic force microscopy of less than about 0.15, more preferably less than about 0.125, and even more preferably less than about 0.10.

In some embodiments, deionized water and methylene iodine (MI) contact angle (CA) may be measured at 5 points, respectively, across a 4-inch wafer were evaluated by AST Optima. The surface energies then can be calculated using the Owens, Wendt, Rabel and Kaelble method based on the water and MI contact angle values. Preferably, the polar energy of the baked underlayer is from about 5 mN/m² to about 50 mN/m², more preferably from about 15 mN/m² to about 35 mN/m². Preferably, the dispersive energy of the underlayer is from about 20 mN/m² to about 50 mN/m², more preferably from about 25 mN/m² to about 40 mN/m².

After the underlayer 18 is formed, a photoresist layer 20 (i.e., imaging layer) having an upper surface 21 is formed on underlayer 18. The preferred photoresist layer 20 is an EUV photoresist, and any commercial EUV photoresist composition can be utilized to form photoresist layer 20. In one embodiment, the photoresist layer 20 is a chemically amplified resist (CAR). In another embodiment, the photoresist layer 20 is a non-chemically amplified resist. In one embodiment, the non-chemically amplified photoresist includes a metal, such as those selected from the group consisting of titanium, zinc, tin, hafnium, zirconium, indium, vanadium, cobalt, molybdenum, tungsten, aluminum, gallium, silicon, germanium, phosphorous, arsenic, yttrium, lanthanum, cerium, lutetium, and mixtures of the foregoing. In another embodiment, the photoresist layer 20 comprises a metal oxide or organometallic compound in the photoresist composition, with suitable metals for the metal oxide (e.g., tin oxide resist, such as those commercially available from Inpria, Inc.) and/or organometallic compound being the same as those listed above.

In some embodiments, the photoresist layer 20 is substantially free of metal. That is, the metal content of the photoresist 20 is less than about 0.005% by weight, preferably less than about 0.001% by weight, and more preferably about 0% by weight, based upon the total weight of the photoresist layer 20 taken as 100% by weight.

Suitable EUV photoresists are available from several commercial suppliers including JSR, TOK, Sumitomo, LAM, Shin Etsu, FujiFilm, Inpria (such as YATU and YATA metal oxide resists), Irresistible Materials, and Zeon.

Regardless of the photoresist type, the photoresist layer 20 can be formed by any conventional method, with one preferred method being spin coating the photoresist composition at speeds of about 350 rpm to about 4,000 rpm (preferably about 1,000 rpm to about 2,500 rpm) and for a time period of about 10 seconds to about 60 seconds (preferably about 10 seconds to about 30 seconds). The photoresist layer 20 is then optionally post-application baked (“PAB”) at a temperature of at least about 70° C., preferably about 80° C. to about 180° C., and more preferably about 100° C. to about 180° C., for about 30 seconds to about 120 seconds. The average thickness of the photoresist layer 20 after baking is typically about 5 nm to about 120 nm, preferably about 10 nm to about 50 nm, and more preferably about 20 nm to about 40 nm.

Referring to FIG. 1(C), a mask 22 is positioned above upper surface 21 of the photoresist layer 20. The mask 22 has exposure portions 24 designed to permit the radiation to reflect from (in the case of EUV radiation) or pass through (in the case of non-EUV radiation) the mask and contact the surface 21 of the photoresist layer 20, thus creating exposed areas 26 on and/or in photoresist layer 20. Mask 22 also includes nonexposure portions 28, which are designed to absorb or block the radiation to prevent the radiation from contacting surface 21 of the photoresist layer 20 in certain areas (i.e., unexposed areas 30), thus resulting in selective exposure of photoresist layer 20. Those skilled in the art will readily understand that the type of mask and the arrangement of reflecting and absorbing portions (i.e., exposure portions 24 and nonexposure portions 28) is designed based upon a desired pattern to be formed in the photoresist layer 20, and ultimately in underlayer 18, any intermediate layers 16, and the substrate 12.

The exposure wavelengths are preferably less than about 20 nm, preferably about 11 nm to about 14 nm, and more preferably about 13.5 nm, i.e., EUV exposure wavelengths.

It will be appreciated that the underlayers 18 as described herein allow for a dose reduction as compared to prior art underlayers. For example, using an underlayer 18 formulated as described herein can result in a dose reduction of about 4 mJ/cm² or more, preferably about 5 mJ/cm² or more, more preferably about 6.5 mJ/cm² or more, and even more preferably about 8 mJ/cm² or more, as compared to the dose that would be required by the same formulation but without the salt. In the same or different embodiments, the use of underlayer 18 results in a dose reduction of about 8% or more, preferably about 10% or more, and more preferably about 13% or more, as compared to the dose that would be required by the same formulation but without the salt. In either case, that dose reduction is achieved while maintaining a usable process window, improving the usable process window, and/or maintaining the same or better bridge and margin collapse.

Regardless of the degree of dose reduction, in some embodiments the typical exposure dose is about 5 mJ/cm² to about 100 mJ/cm², preferably from about 10 mJ/cm² to about 80 mJ/cm², and more preferably from about 20 mJ/cm² to about 60 mJ/cm². In other embodiments, the exposure dose is about 5 mJ/cm² to about 80 mJ/cm², preferably about 10 mJ/cm² to about 60 mJ/cm², and more preferably about 20 mJ/cm² to about 55 mJ/cm².

After exposure, the photoresist layer 20 is optionally subjected to a post-exposure bake (PEB) at a temperature of less than about 220° C., preferably about 60° C. to about 200° C., and more preferably about 80° C. to about 180° C., for about 20 seconds to about 120 seconds, and preferably about 30 seconds to about 90 seconds. The time and temperature can vary depending on the specific photoresist.

The photoresist layer 20 is then contacted with a developer to form a pattern 32 in the photoresist layer 20′ (FIG. 1(D)), with the pattern 32 including trenches 34 and raised features 36. Depending upon whether the photoresist used is positive-working or negative-working, the developer either removes the exposed portions of the photoresist layer 20′ or removes the unexposed portions of the photoresist layer 20′ to form the pattern. The pattern 32 is then transferred to the underlayer 18, any present intermediate layers 16 (e.g., hardmask layer), and finally the substrate 12. This pattern transfer can take place via plasma etching (e.g., CF₄ etchant, O₂ etchant) or a wet etching or developing process. In embodiments where the pattern is transferred from the photoresist layer 20′ to the substrate 12 via etching, it is preferred that the etch rate of the underlayer 18 relative to the EUV photoresist being used (e.g., a CAR photoresist, a non-CAR photoresist, or an organometallic photoresist) is at least about 1×, and preferably about 1.5× to about 2×.

Regardless of whether pattern transfer is effected by etching or by developing, the resulting features can have high resolutions and little to no bridging, which can be determined via visual observation of SEM images, and/or by using a brightfield inspection tool (e.g., KLA-Tencor 2139, by KLA Instruments) to look for defects in patterns. For example, in some embodiments, resolutions of less than about 40 nm half pitch, and preferably less than about 28 nm half pitch, more preferably less than about 20 nm half pitch, and still more preferably less than about 14 nm half pitch can be achieved with the inventive method. In other embodiments, resolutions of less than about 20 nm half pitch, and preferably less than 15 nm half pitch, can be achieved with the inventive method.

Additional advantages of the various embodiments will be apparent to those skilled in the art upon review of the disclosure herein and the working examples below. It will be appreciated that the various embodiments described herein are not necessarily mutually exclusive unless otherwise indicated herein. For example, a feature described or depicted in one embodiment may also be included in other embodiments but is not necessarily included. Thus, the present disclosure encompasses a variety of combinations and/or integrations of the specific embodiments described herein.

As used herein, the phrase “and/or,” when used in a list of two or more items, means that any one of the listed items can be employed by itself or any combination of two or more of the listed items can be employed. For example, if a composition is described as containing or excluding components A, B, and/or C, the composition can contain or exclude A alone; B alone; C alone; A and B in combination; A and C in combination; B and C in combination; or A, B, and C in combination.

The present description also uses numerical ranges to quantify certain parameters relating to various embodiments. It should be understood that when numerical ranges are provided, such ranges are to be construed as providing literal support for claim limitations that only recite the lower value of the range as well as claim limitations that only recite the upper value of the range. For example, a disclosed numerical range of about 10 to about 100 provides literal support for a claim reciting “greater than about 10” (with no upper bounds) and a claim reciting “less than about 100” (with no lower bounds).

### EXAMPLES

The following examples set forth methods in accordance with the disclosure. It is to be understood, however, that these examples are provided by way of illustration, and nothing therein should be taken as a limitation upon the overall scope.

### Underlayer Evaluation Methods

For examples using EUV lithography targeting the feature 14L/28P, EUV exposure was performed at imec using an NXE3400B EUV scanner. All of the underlayers for EUV lithography evaluation were hand dispensed and spin-coated onto a virgin wafer followed by baking at an appropriate temperature (160° C. or 205° C.) for 1 minute. The MOR was then applied to the baked underlayer, followed by baking, exposure, and post-exposure baking to form the MOR. The MORs were coated on top of the UL to print 1:1 line/space (L/S) at pitch 28 nm. The focus exposure matrices (FEMs) and cross-section profiles at the best dose/focus of the MORs on virgin silicon wafers are shown in corresponding figures. Biased LWR and line edge roughness LER, were measured from the pictures obtained by a scanning electron microscope (Hitachi CG6300 top-down CD-SEM). L/S cross-sections at the sizing dose and optimal focus were evaluated by SEM.

### Example 1

### Synthesis of Compound 1

In a clean, single-neck round bottom flask equipped with a stir bar, 5.43 g of (propylene glycol methyl ether) PGME and 1.45 g of 3-iodopropyltrimethoxysilane were added. The solution was then mixed for five minutes. In a separate vial, 10 g of PGME and 1.03 g of imidazole were vigorously shaken, until all of the imidazole was dissolved into the PGME. This mixture was then added dropwise into the round bottom flask and stirred constantly at 380 rpm. Next, the flask was plugged with a stopper and mixed for six hours at room temperature. After mixing for six hours, the solution was transferred from the flask into a clean Aicello bottle and stored in a freezer. A small aliquot of the solution was then taken for a ¹H nuclear magnetic resonance (NMR) analysis. The final solution was recorded to be about ten percent solid. The resulting polymer with the salt bound thereto is shown below.

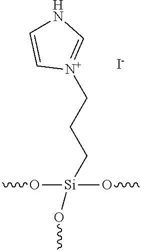

### Example 2

### Formulation of EUV Underlayer A

To a clean Aicello bottle, 0.2600 g of Compound 1, 2.500 g of DI water, and 22.26 g of PGME were added. The solution was mixed for an hour before use. The final percent solids was recorded to be 0.1 percent, resulting in a formulation tailored to produce a spin-coated underlayer having a thickness of about 1.2 nm.

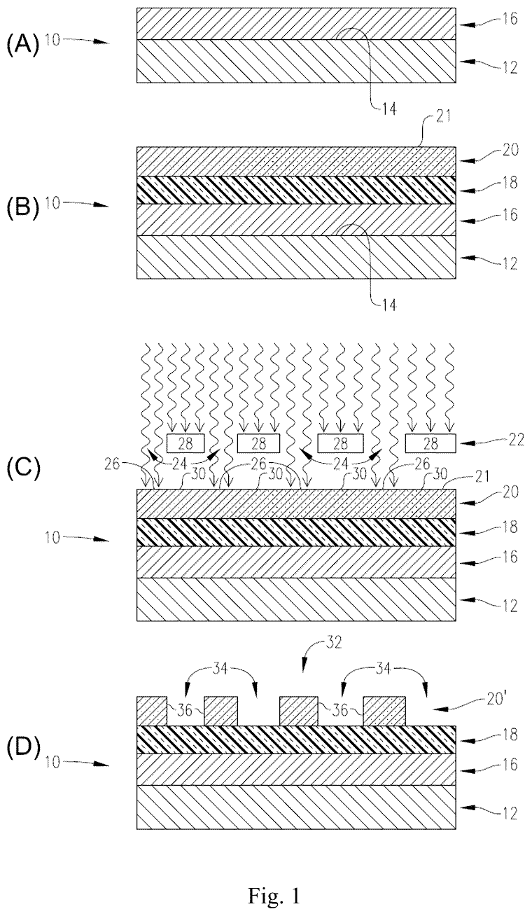

EUV lithography testing of Underlayer A carried out as described previously exhibited a dose of 54.6 mJ with respect to P28 lines. When compared to a non-ionic, silicon-containing underlayer as prepared in Example 21 tested under similar conditions, a dose reduction of approximately 20% was observed. The focus exposure matrix and an SEM image of the formed features are shown in FIG. 2.

### Comparative Example 3

### Synthesis of Compound C2

In a clean, single-neck round bottom flask equipped with a stir bar, 10.08 g of DI water and 1.38 g of triethoxy-3-(2-imidazolin-1-yl)propylsilane (IMIDTEOS) were added. This solution was then mixed for 5 minutes at 380 rpm. In a separate vial, 10 g of DI water and 0.87 g of p-tolylsulfonic acid (p-TSA) were shaken vigorously until all of the p-TSA was dissolved into the DI water. This mixture was then added dropwise into the round bottom flask while being stirred constantly at 380 rpm. Next, the flask was plugged with a stopper and set to mix for 20 hours at 380 rpm and room temperature. After mixing for 20 hours, the solution was bottled and stored in a freezer. The resulting polymer with the salt bound thereto is shown below.

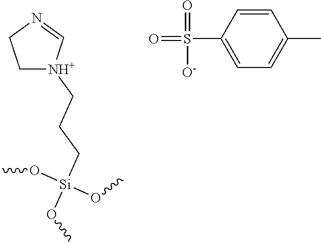

### Comparative Example 4

### Formulation of EUV Underlayer C-B

To a clean Aicello bottle, 0.259 g of the Compound 2 from Example 3, 12.7040 g of DI water, and 12.9731 g of PGME were added. The solution was mixed for an hour before use at 30 rpm. The final percent solids was recorded to be 0.1 percent, resulting in a composition tailored to produce a spin-coated underlayer having a thickness of about 3.5 nm.

### Example 5

### Synthesis of Compound 3

In a clean, three-neck round bottom flask equipped with a stir bar, 75.18 g of PGME and 12.31 g of triethoxysilylpropylethylcarbamate (TEOSPEC) were added. This solution was mixed for 5 minutes. In a separate vial, 6.82 g of 0.01M HNO₃ was weighed, then added dropwise to the round bottom flask while stirring constantly. The flask was plugged with a stopper and stirred for 30 minutes at 380 rpm and room temperature. After 30 minutes, the flask was connected to a reflux setup and equipped with nitrogen gas flow. The mixture ran for 10 hours at 90° C., including time to raise to temperature within the 10 hours. The solution was then allowed to cool to room temperature, bottled, and stored in a freezer. The resulting polymer had the structure shown below.

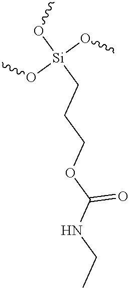

### Example 6

### Synthesis of Compound 4

In a clean, three-neck round bottom flask equipped with a stir bar, 80.44 g of PGME and 12.93 g of n-(3-triethoxysilylpropyl)-4-hydroxybutyramide (HATEOS) were added. This solution was mixed for 5 minutes. In a separate vial, 6.81 g of 0.01M HNO₃ was weighed and then added dropwise to the round bottom flask while stirring constantly. The flask was plugged with a stopper and allowed to stir for 30 minutes at 380 rpm and room temperature. After 30 minutes, the flask was connected to a reflux setup and equipped with nitrogen gas flow. The mixture was run for 10 hours at 70° C., including time to rise up to temperature within the 10 hours. The solution was then allowed to cool to room temperature, bottled, and stored in a freezer. The resulting polymer had the structure shown below.

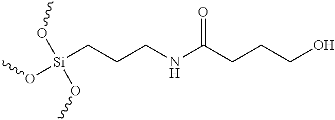

### Example 7

### Formulation of EUV Underlayer C

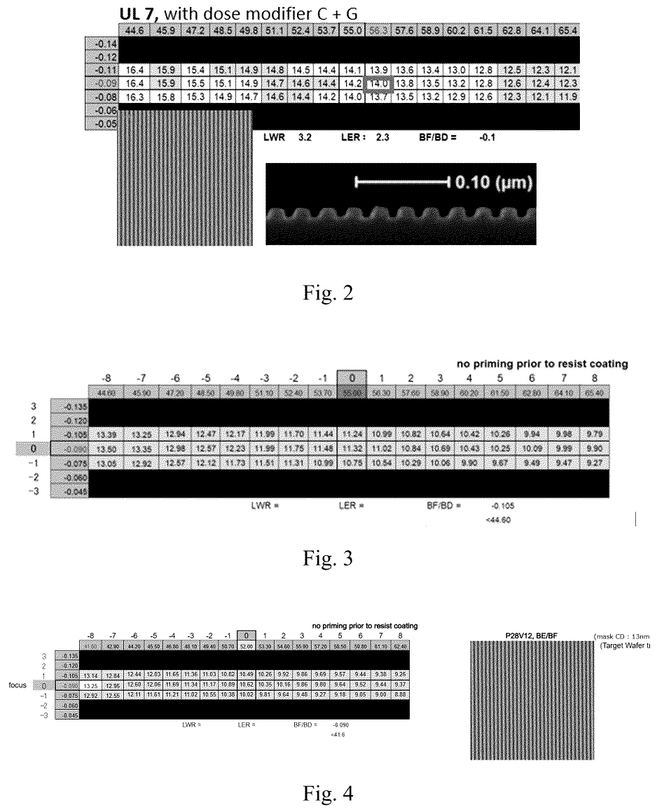

To a clean Aicello bottle, 4.2569 g of Compound 1 from Example 1 (10% solids in PGME), 1.5799 g of Compound 4 from Example 6 (9.04% solids in PGME), 11.297 g of pyridinium p-toluene sulfonate (PpTS) solution (0.2% in PGME), and 63.6441 g of PGME were added. The solution was mixed for an hour before use. This material was spin-coated at 1,500 rpm for 60 seconds and baked at 160° C. for 60 seconds to generate a film having a thickness of 10 nm. The focus exposure matrix is shown in FIG. 3.

### Example 8

### Formulation of EUV Underlayer D

To a clean 100-ml Aicello bottle, 50.9659 g of PGME, 4.6005 g of Compound 1 from Example 1 (10% in PGME), and 1.6925 g of Compound 4 from Example 6 (9.04% in PGME) were added. The solution was mixed for an hour prior to use. This material was spin-coated at 1,500 rpm for 60 seconds and baked at 205° C. for 60 seconds to generate 10-nm thick film. The focus exposure matrix and an SEM image of the formed lines are shown in FIG. 4.

The formulation tested in Example 7 was processed with an old reticle while the formulation tested in this Example 8 was processed with a new reticle. Taking into consideration the similarities between the formulations tested in Examples 7 and 8, and accounting for the additional dose reduction seen with the new reticle, it can be inferred that the addition of PpTS in the sample provided an added dose reduction, but is not the entire contributor to dose reduction of the material.

### Example 9

### Formulation of EUV Underlayer E

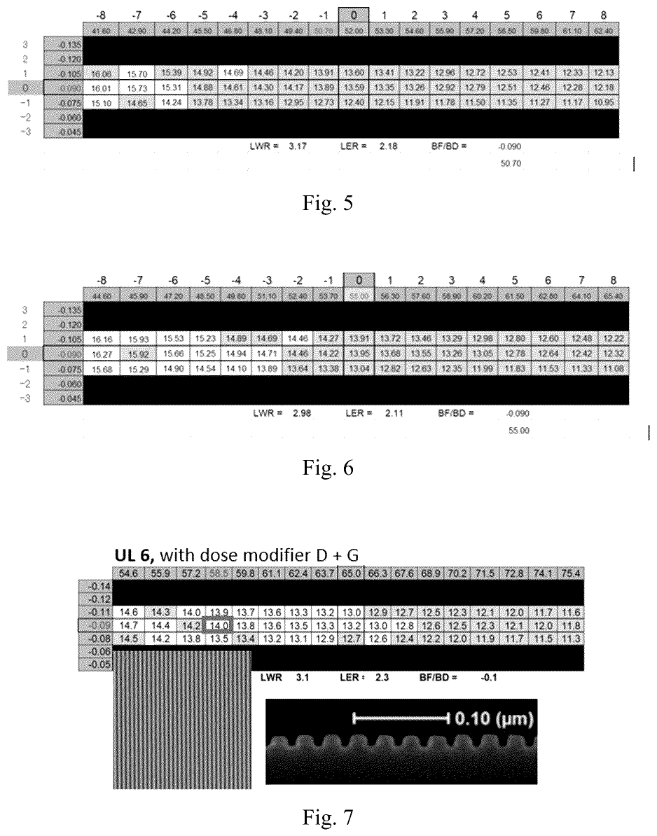

To a clean 100-ml Aicello bottle, 47.14 g of PGME, 1.39 g of Compound 4 of Example 6 (9.04% solids in PGME), 1.26 g of Compound 1 of Example 1 (10% solids in PGME), and 0.31 g of PpTS solution (4% in PGME) were added. The solution was mixed for an hour prior to use. When spin-coated at 1,500 rpm for 60 seconds and baked at 160° C. for 60 seconds, the film thickness was recorded to be about 10 nm. The focus exposure matrix is shown in FIG. 5.

### Example 10

### Formulation of EUV Underlayer F

To a clean 100-ml Aicello bottle, 47.87 g of PGME, 1.55 g of Compound 4 of Example 6 (9.04% solids in PGME), 0.46 g of Compound 1 of Example 1 (10% solids in PGME), and 0.23 g of PpTS solution (4% in PGME) were added. The solution was mixed for an hour prior to use. When spin-coated at 1,500 rpm for 60 seconds and baked at 160° C. for 60 seconds, the film was recorded to be about 10 nm. The focus exposure matrix is shown in FIG. 6.

When comparing dose-to-size of Underlayer D (75% by weight of total polymer in formulation being ionic), Underlayer E (50% by weight of total polymer in formulation being ionic), and Underlayer F (25% by weight of total polymer in formulation being ionic), a clear influence of the ionic contents is demonstrated. Underlayer D, having the highest ionic concentration of the three materials, has a significantly lower dose than Underlayer E or Underlayer F, and the doses trend negatively with ionic concentration of the polymer/small molecule composition.

### Example 11

### Synthesis of Compound 5

To a clean single neck round-bottom flask, 32.72 g of PGME and 2.08 g of N,N-(dimethylaminopropyltrimethoxysilane) (DMAPTMS) were added, and the solution was stirred for 10 minutes. Next, 1.56 g of iodoethane was weighed in a separate container then added dropwise into the flask, while stirring constantly. The resulting mixture was stirred at room temperature for 24 hours. The solution was then bottled and stored in a freezer. The resulting compound had the structure shown below.

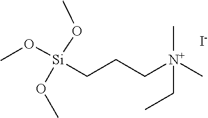

### Example 12

### Formulation of EUV Underlayer G

To a clean 100-ml Aicello bottle, 41.38 g of PGME, 10.38 g of PGMEA, and 0.27 g of Compound 5 of Example 11 (10% in PGME) were added, then mixed for an hour prior to use. The resulting material was about 0.05% solids, resulting in a composition tailored to produce a film having a thickness of about 2 nm. When the composition was spun at 1,500 rpm for 60 seconds and baked at 160° C. for 60 seconds, the film had thickness of about 2 nm. The focus exposure matrix and an SEM image of the formed features are shown in FIG. 7.

### Example 13

### Synthesis of Compound 6

To a clean single neck round-bottom flask, 31.51 g of PGME, 5.51 g of triethoxysilylpropylsuccinicanhydride (TEOSPSA), and 0.59 g of 3-iodopropyltrimethoxysilane were added and mixed for 10 minutes. Then, 3.62 g of DI water was weighed separately and added to the mixture dropwise while stirring continuously. The resulting mixture was allowed to stir for 24 hours at room temperature. After the 24-hour stirring period, 0.15 g of imidazole was added to the flask, then the solution was allowed to mix an additional four hours at room temperature. The resulting polymer had the structure shown below.

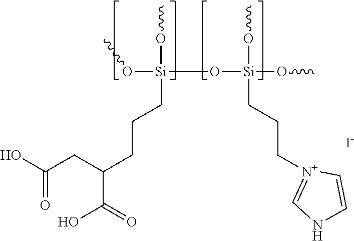

### Example 14

### Formulation of EUV Underlayer H

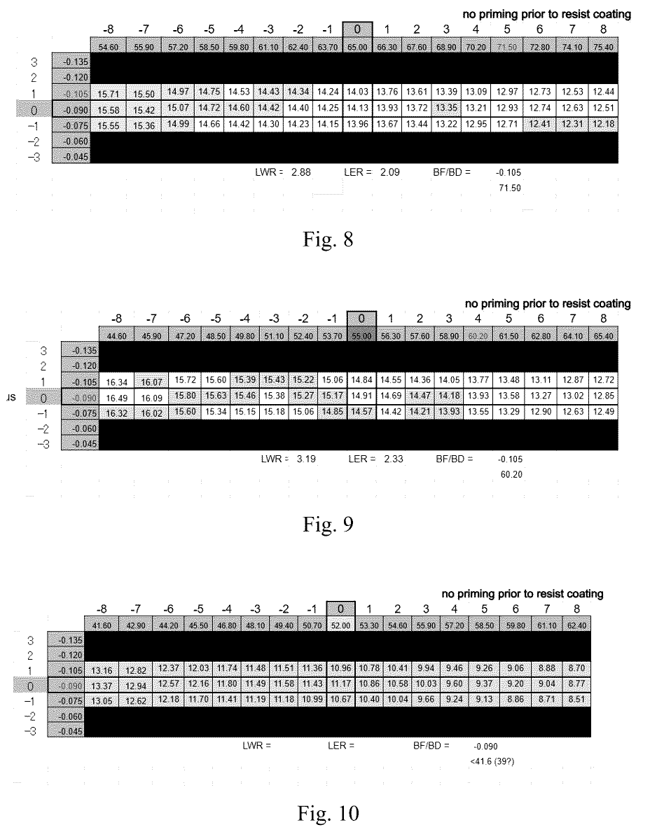

To a clean 100-ml Aicello bottle, 51.8239 g of PGME and 0.1866 g of Compound 6 (1% in PGME) were added, then mixed for an hour prior to use. The resulting material was about 0.05% solid, resulting in a composition tailored to produce a film having a thickness of about 2 nm. When the composition was spun at 1,500 rpm for 60 seconds and baked at 160° C. for 60 seconds, the resulting film had a thickness of about 2 nm. The focus exposure matrix is shown in FIG. 8.

### Example 15

### Synthesis of Compound 7

In a clean, single-neck flask, 16.5 g of PGME and 1.48 g of 3-iodopropyltrimethoxysilane (IPTMS) were added. The solution was allowed to stir at room temperature for 10 minutes. Then, 1.43 g of 1-vinylimidazole was weighed and added to the flask dropwise, while stirring continuously. The resulting mixture was allowed to stir at room temperature for 6 hours. The remaining solution was stored in a freezer. The resulting structure is shown below.

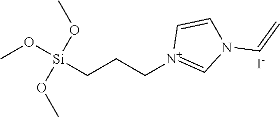 [SMILES: C=Cn1cc[n+](CCC[Si](OC)(OC)OC)c1 ; [I-]]

### Example 16

### Formulation of EUV Underlayer I

To a clean 100-ml Aicello bottle, 49.03 g of PGME, 5.52 g of DI water, and 0.56 g of Compound 7 of Example 15 (10% solids) were added, then mixed for an hour prior to use. The resulting material was about 0.10 percent solids, resulting in a composition tailored to produce a film having a thickness of about 1 nm. When the composition was spun at 1,500 rpm for 60 seconds and baked at 160° C. for 60 seconds, the resulting film had a thickness of about 1 nm. The focus exposure matrix is shown in FIG. 9.

### Example 17

### Synthesis of Compound 8

To a clean 3-neck 100 ml round bottom flask, 10.41 g of 2-(carbomethoxy)ethyltrimethoxysilane and 36.65 g of PGME were added, then set to mix for 10 minutes at room temperature. Next, 9.001 g of 0.01M HNO₃ solution was added dropwise to the solution while stirring continuously. The contents were allowed to mix for an additional 45 minutes, then refluxed at 90° C. for 11 hours in an oil bath (starting from room temperature). The product was stored in a freezer. The resulting polymer had the structure shown below.

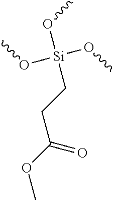

### Example 18

### Synthesis of Compound 9

To a clean single neck flask, 24.13 g of PGME and 2.76 g of IMIDTEOS were added and stirred at room temperature for 10 minutes. Then, 0.54 g of DI water was added dropwise to the mixture. The resulting solution was then allowed to stir at room temperature for 20 hours. After stirring for 20 hours, the material was stored in a freezer. The solution was recorded to be about 10 percent solids. The resulting polymer had the structure shown below.

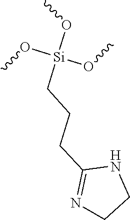

### Example 19

### Formulation of EUV Underlayer J

To a clean 100-ml Aicello bottle, 49.2484 g of PGME, 4.5476 g of Compound 1 (10% in PGME), and 1.2205 g of Compound 8 (12.4% in PGME) were added, then mixed for an hour prior to use. The material was spun at 1,500 rpm for 60 seconds then baked at 160° C. for 60 seconds. Under these conditions, with a solids composition of 1.10% solids, the material exhibited a film thickness of about 10 nm. The focus exposure matrix is shown in FIG. 10.

When comparing Underlayer J to Underlayer D, it was demonstrated that the ionic component of the aforementioned samples is responsible for a significant portion of dose reduction. Both materials contained 75% loading (relative to the total polymer solids) of ionic components, and 25% of a non-ionic polymer (relative to the total polymer solids), and no additional additives. Both materials contained the same ionic small molecule and showed a very similar dose reduction.

### Example 20

### Synthesis of Compound 10

To a clean 100 ml 3-neck flask, 4.92 g of 2-(3,4-epoxycyclohexyl)ethyltrimethoxysilane (ECHTMS) and 16.47 g of PGME were added and then mixed for 10 minutes at room temperature. Next, 3.63 g of 0.01M HNO₃ solution was added dropwise to the mixture while stirring continuously. The contents were allowed to mix for an additional 45 minutes then refluxed at 90° C. for 11 hours in an oil bath (starting from room temperature). The product was stored in a freezer. The resulting polymer is shown below.

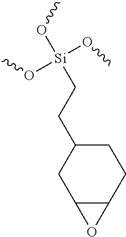

### Example 21

### Formulation of EUV Underlayer K

To a clean 100-ml Aicello bottle, 62.8387 g of PGME was added, followed by 5.4166 g of Compound 9 (10% in PGME) and 1.8557 g of Compound 3 (9.80% solids in PGME). The contents were mixed an hour prior to use. The resulting material was about 1.03 wt. % solids, resulting in a composition tailored to produce a film having a thickness of about 10 nm. When spin-coated at 1,500 rpm for 60 seconds then baked at 205° C. for 60 seconds, the material had a thickness of about 10 nm. The focus exposure matrix is shown in FIG. 11.

### Example 22

### Formulation of EUV Underlayer L

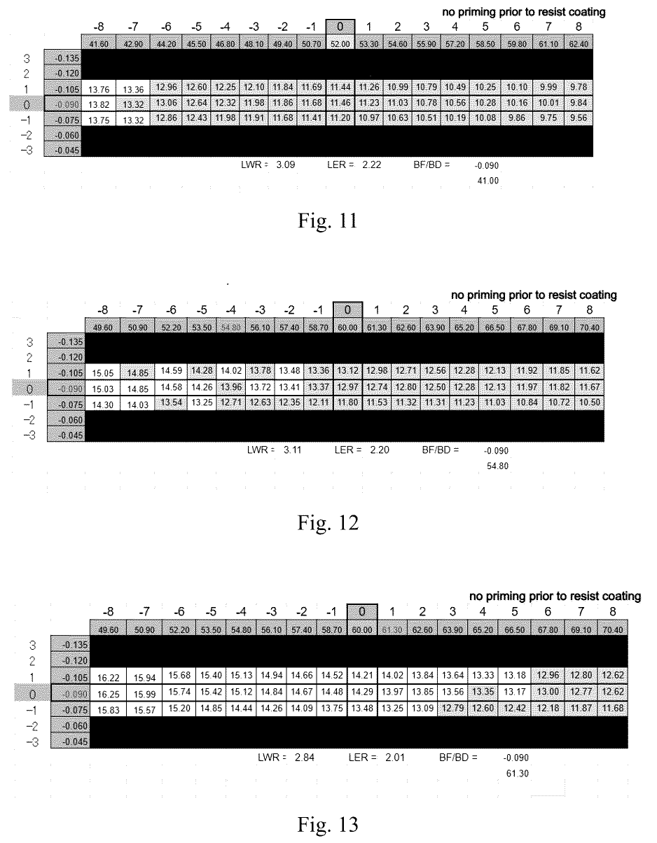

In a clean 100-ml Aciello bottle, 95.8 g of PGME, 3.74 g of Compound 9 (10% in PGME), 0.11 g of glycidylPOSS (EP0409, Hybrid Plastics), and 0.47 g of PpTS solution (4% in PGME) were added. The contents (0.5% solids) were mixed for an hour prior to use, resulting in a composition tailored to form a film having a thickness of about 10 nm. When spin-coated at 1,500 rpm for 60 seconds and baked at 205° C. for 60 seconds, the film was recorded to be about 10 nm. The focus exposure matrix is shown in FIG. 12.

### Example 23

### Formulation of EUV Underlayer M

In a clean 100-ml Aciello bottle, 48.61 g of PGME, 0.56 g Compound 9 (10% in PGME), and 0.85 g of Compound 10 (15% in PGME) were added. The contents (0.37% solids) were mixed for an hour prior to use and resulting in a composition tailored to produce a film having a thickness of about 10 nm. When spin-coated at 1,500 rpm for 60 seconds and baked at 205° C. for 60 seconds, the resulting film was about 10 nm thick. The focus exposure matrix is shown in FIG. 13.

### Example 24

### Formulation of EUV Underlayer N

In a clean 100-ml Aciello bottle, 50.2014 g PGME, 1.299 g of Compound 4 (9.04% solids) and 3.5728 g of Compound 9 were added. The solution was mixed for an hour prior to use. The material was recorded to be about 0.87 percent solids, resulting in a composition tailored to form a film having a thickness of about 10 nm. When the composition was spun at 1,500 rpm for 60 seconds and baked at 205° C. for 60 seconds the thickness was about 10 nm.

### Example 25

### Synthesis of Compound 11

To a clean single-neck flask, 22.48 g of PGME and 2.12 g of 1,8-diiodooctane were added then stirred at room temperature for 10 minutes. Next, 0.40 g of imidazole was added to the flask, and the mixture was allowed to stir at room temperature for 24 hours. The resulting product had about 10 percent solids. The composition was stored at room temperature. The resulting product had the structure shown below.

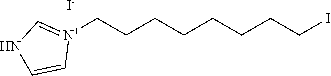 [SMILES: [I-] ; ICCCCCCCC[n+]1cc[nH]c1]

### Example 26

### Synthesis of Compound 12

In a clean tripour, 163.80 g of PGME was weighed. Then, the majority of the PGME was added to a 1 L reactor, equipped with a stir motor. The motor was set to 300 rpm. In a different tripour, 20.00 g of 2-hydroxyethylacrylate, 7.93 g of N-(2-hydroxyethyl) acrylamide, 10.76 g of styrene, and 2.26 g of azobisisobutyronitrile were weighed, then transferred to the reactor. The remaining PGME was added to the reactor to rinse. For 60 minutes, the reactor rose from room temperature to 70° C., where it remained for 16 hours. After 16 hours, the temperature was then lowered back to room temperature over 30 minutes. The product was then stored at room temperature. The product was recorded to be about 20 wt. % solids. The resulting product had the structure shown below.

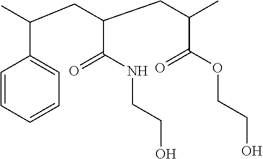 [SMILES: CC(CC(CC(C)c1ccccc1)C(=O)NCCO)C(=O)OCCO]

### Example 27

### Formulation of EUV Underlayer O

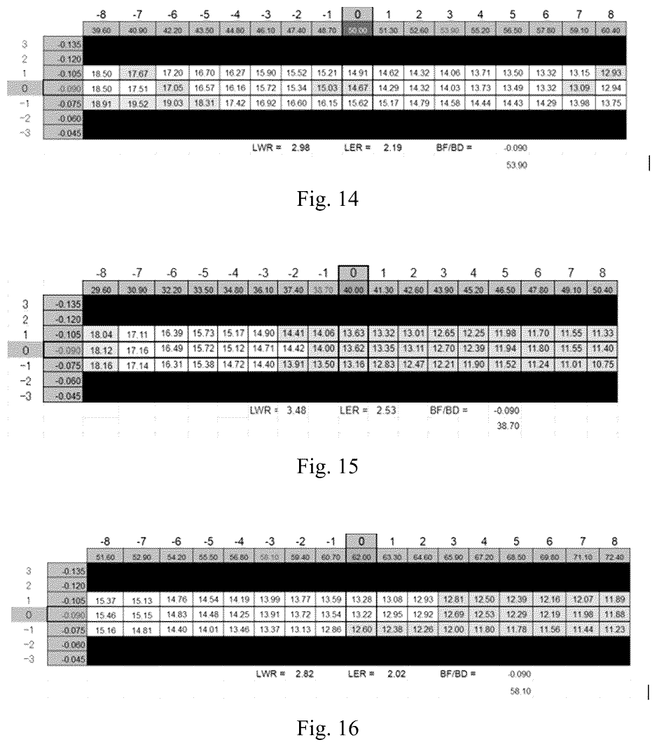

In a clean 100-ml Aicello bottle, 44.16 g of PGME, 5.03 g of PGMEA, 0.67 g of Compound 12 (20% in PGME, Brewer Science, Inc.), 0.15 g of Compound 11 (10% in PGME, Brewer Science, Inc.), and 0.17 g of PpTS solution (4% in PGME, Brewer Science, Inc.) were added. The contents were mixed for an hour prior to use and had 0.31 percent solids, yielding a composition tailored for producing a film having a thickness of about 10 nm. When spin-coated at 1,500 rpm for 60 seconds and baked 205° C. for 60 seconds, the film was recorded to be about 10 nm thick. The focus exposure matrix is shown in FIG. 14.

### Example 28

### Synthesis of Compound 13

In a clean single-neck round bottom flask, 17.01 g of PGME, 1.54 g of n-(3-triethoxysilylpropyl)-4-hydroxybutyramide (HATEOS), and 1.45 g of IPTMS were added. The contents were stirred for 10 minutes. Later, 1.81 g of 0.01M HNO₃ solution was added to the flask dropwise, and the mixture continued to stir at room temperature for 24 hours. The material was stored in a freezer. The resulting product had the structure shown below.

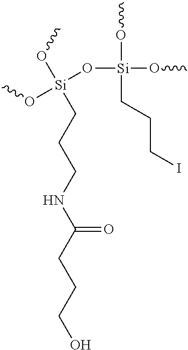

### Example 29

### Formulation of EUV Underlayer P

To a clean 250 ml Aicello bottle, 144.2691 g of PGME and 6.2413 g of Compound 13 were added and then mixed for an hour prior to use. The material was recorded to be about 0.41% by wt. solids and exhibited a film thickness of about 10 nm when spun at 1,500 rpm for 60 seconds and baked at 160° C. for 60 seconds. The focus exposure matrix is shown in FIG. 15.

### Example 30

### Synthesis of Compound 14

In a clean single-neck round bottom flask, 10.47 g of PGME, 0.77 g of n-(3-triethoxysilylpropyl)-4-hydroxybutyramide (HATEOS), and 0.43 g of iodoethane were added. The mixture was then left to stir at room temperature for 8 hours. After mixing, the material was stored in a freezer. The resulting polymer with a salt bound thereto is shown below.

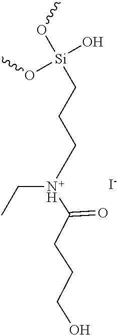

### Example 31

### Formulation of EUV Underlayer Q

To a clean 100-ml Aicello bottle, 54.76 g of PGME and 0.29 g of Compound 14 were added then mixed for an hour on a mixing roller at 30 rpm prior to use. The formulation was recorded to be about 0.05% by wt. solids. When the material was spin-coated at 1,500 rpm for 60 seconds then baked at 160° C. for 60 seconds, the material exhibited a film thickness of about 2 nm.

### Example 32

### Formulation of EUV Underlayer R

To a clean 100-ml Aicello bottle, 48.71 g of PGME, 1.10 g of ECHTMS, and 1.07 g of 3-(N,N-dimethylaminopropyl) trimethoxysilane (DMAPTMS) were added then mixed at room temperature for 1 hour prior to use. The formulation was recorded to be about 4.26% by wt. solids. When spin-coated at 1,500 rpm for 60 seconds and baked at 205° C. for 60 seconds, the film was recorded to be about 5 nm thick. The focus exposure matrix is shown in FIG. 16.

### Example 33

### Formulation of EUV Underlayer S

To a clean 100-ml Aicello bottle, 54.9266 g of PGME, 0.0570 g of (3-glycidoxypropyl)methyldiethoxysilane (GlyDEOS) and 0.0605 g of DMAPTMS were added followed by mixing at room temperature for 1 hour prior to use. The formulation was recorded to be about 0.21% by weight solids. When spin-coated at 1,500 rpm for 60 seconds and baked at 205° C. for 60 seconds, the film was recorded to be about 1 nm thick.

### Comparative Example 34

### Formulation of EUV Underlayer C-T

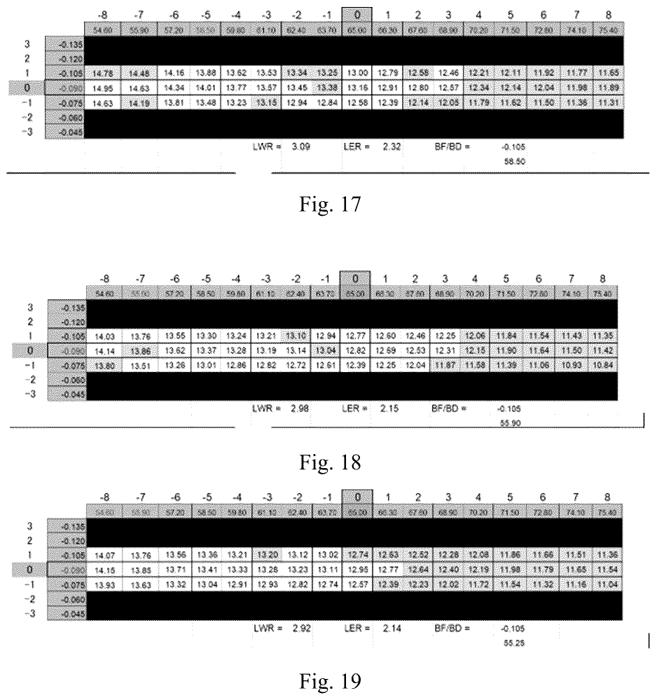

To a clean 100-ml Aicello bottle, 0.9129 g of Compound 4 (9.04% solids in PGME), 1.6440 g of PpTS solution (0.2% PpTS in PGME), and 52.4984 g of PGME were added, and the solution was mixed for an hour before use. The formulation was recorded to be 0.16% by weight solids, with an approximated thickness of 5 nm. The focus exposure matrix is shown in FIG. 17.

### Comparative Example 35

### Formulation of EUV Underlayer C-U

To a clean 100-ml Aicello bottle, 0.3001 g of Compound 3 (9.80% solids in PGME), and 52.7504 g of PGME were added. The solution was then mixed for an hour before use. After mixing, the formulation was recorded to be 0.05 percent solids with an approximated thickness of 2 nm. The focus exposure matrix is shown in FIG. 18.

### Comparative Example 36

### Formulation of EUV Underlayer C-V

To a clean 100-ml Aicello bottle, 0.2827 g of Compound 3 (9.80% solids in PGME), 0.5232 g of PpTS solution (0.2% solids in PGME), and 54.2514 g of PGME were added, and the solution was mixed for an hour before use. The formulation was recorded to be 0.05% by weight solids, with an approximate film thickness of 2 nm. The focus exposure matrix is shown in FIG. 19.

### Comparative Example 37

### Formulation of EUV Underlayer C-X

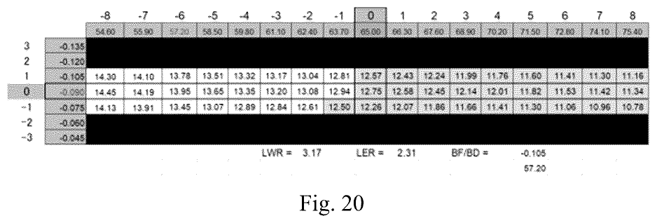

To a clean 100-ml Aicello bottle, 0.9373 g of Compound 4 (9.04% in PGME) and 54.2442 g of PGME were added, and the solution was mixed for an hour before use. The resulting formulation was recorded to be 0.15% by weight solids, with an approximated thickness of 5 nm. The focus exposure matrix is shown in FIG. 20.

### Comparative Example 38

### Synthesis of Silicon Compound C16

To a three-neck round bottom flask equipped with a stir bar, 14.25 g of PGME and 2.92 g of methacrylamidopropyltriethoxysilane were added. The solution was mixed for 10 minutes at room temperature. Next, 1.83 g of 0.01M HNO₃ solution was added to the flask dropwise, while stirring continuously. The mixture was left to stir for an additional 45 minutes at room temperature, after which it was added to a reflux setup with oil bath, equipped with nitrogen flow. The solution was allowed to reflux for 11 hours in a 70° C. oil bath, starting from room temperature. The product was recorded to be about 10% by weight solids. After mixing, the material was stored in a freezer. The resulting product had the structure shown below.

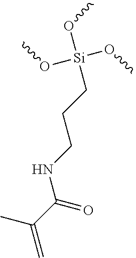

### Comparative Example 39

### Formulation of EUV Underlayer C-Y

To a clean 100-ml Aicello bottle, 48.69 g of PGME and 1.43 g of Compound C16 (10% solids) were added, and the solution was mixed for an hour prior to use. The formulation was recorded to be about 0.29% by weight solids. When spin-coated at 1,500 rpm for 60 seconds and baked at 205° C. for 60 seconds, the material had a recorded thickness of about 10 nm.

### Comparative Example 40

### Formulation of EUV Underlayer C-Z

To a clean 100-ml Aicello o bottle, 49.62 g of PGME and 0.97 g of aminopropyltriethoxysilane were added, and the solution was mixed for an hour prior to use. The resulting material was recorded to be 1.92% by weight solids. When spin-coated at 1,500 rpm for 60 seconds and baked at 205° C. for 60 seconds, the film had a recorded thickness of 5 nm.

### Comparative Example 41

### Formulation of EUV Underlayer C-AA

To a clean 100-ml Aicello bottle, 47.34 g of PGME and 20.977 g of Compound 9 (10% in PGME) were added followed by mixing for an hour prior to use. The resulting material was recorded to be 3.07% by weight solids, exhibiting a film thickness of about 8 nm when spun at 1,500 rpm for 60 seconds and baked at 205° C. for 60 seconds.

### Comparative Example 42

### Formulation of EUV Underlayer C-AB

To a clean 100-ml Aicello bottle, 54.9559 g of PGME and 0.0645 g of dimethylaminopropyltrimethoxysilane (DMAPTMS) were added, and the solution was mixed for an hour prior to use. The resulting material was recorded to be about 0.11% by weight solids and had a film thickness of about 2 nm when spun at 1,500 rpm for 60 seconds and baked at 205° C. for 60 seconds. The resulting product had the structure shown below.

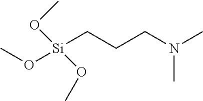

### Example 43

### Formulation of EUV Underlayer C-AC

To a clean 100-ml Aicello bottle, 55.0041 g of PGME and 0.0591 g of methacrylamidopropyltrimethoxysilane were added, and the solution was mixed for an hour prior to use. The resulting material was recorded to be about 0.11% by weight solids, and had a film thickness of about 2 nm when spun at 1,500 rpm for 60 seconds and baked at 205° C. for 60 seconds. The resulting product had the structure shown below.

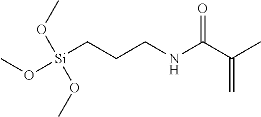 [SMILES: C=C(C)C(=O)NCCC[Si](OC)(OC)OC]

### Example 44

### Synthesis of Compound 17

To a three-neck round bottom flask equipped with a stir bar, 0.038 g of azobisisobutyronitrile, 0.751 g of 4-cyano-4-(((dodecylthio) carbonothioyl)thio)pentanoic acid (BM1432), 9.197 g of 2-hydroxyethylacrylate, 0.1818 g of 1-(3-sulfopropyl)-2-vinylpyridinium hydroxide inner salt (SPV), 8.1341 g of deionized water, and 32.5367 g of PGME were weighed. The round bottom flask was sealed with a rubber septum and mixed for 5 minutes at 500 rpm resulting in a transparent solution with yellow/orange color. Next, the material was sparged with nitrogen for 10 minutes using a transfer needle and release needle for pressure equilibration. After sparging, the round bottom flask was placed in a preheated oil bath at 60° C. and reacted for 24 hours while mixing at 350 rpm. The product was then downbottled and stored at room temperature. The product was recorded to be about 20% by weight solids. The resulting product had the structure shown below.

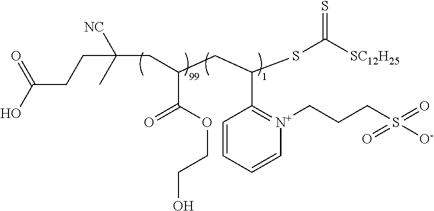

### Example 45

### Formulation of EUV Underlayer AD

In a clean 100-ml Aicello bottle, 97.90 g of PGME, 0.89 g of deionized water, 0.67 g of Compound 17 (20% in a 80:20 PGME: deionized water solution), and 0.54 g of PpTS solution (1% in PGME, Brewer Science, Inc.) were added. The contents were mixed for an hour prior to use and had 0.14% by weight solids. When spin-coated at 1,500 rpm for 60 seconds and baked 230° C. for 60 seconds, the film was recorded to be about 5 nm thick.

### Example 46

### Synthesis of Compound 18

To a three-neck round bottom flask equipped with a stir bar, 0.039 g of azobisisobutyronitrile, 0.769 g of 4-cyano-4-(((dodecylthio) carbonothioyl)thio)pentanoic acid (BM1432), 9.104 g of 2-hydroxyethylacrylate, 0.3636 g of 1-(3-sulfopropyl)-2-vinylpyridinium hydroxide inner salt (SPV), 12.3305 g of deionized water, and 28.7713 g of ethyl lactate were weighed. The round bottom flask was sealed with a rubber septum and mixed for 5 minutes at 500 rpm resulting in a cloudy solution with yellow color. Next, the material was sparged for 10 minutes with nitrogen using a transfer needle and release needle for pressure equilibration. After sparging, the round bottom flask was placed in a preheated oil bath at 60° C. and reacted for 24 hours while mixing at 350 rpm. The resulting solution was transparent and orange in color. The product was then downbottled and stored at room temperature. The product was recorded to be about 20% by weight solids. The resulting product had the structure shown below.

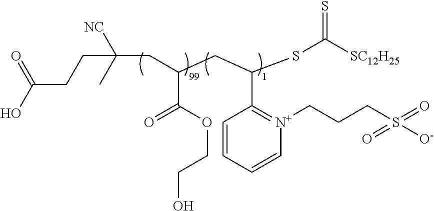

### Example 47

### Formulation of EUV Underlayer AE

In a clean 100-ml Aicello bottle, 49.51 g of ethyl lactate, 48.33 g of PGME, 0.82 g of deionized water, 0.75 g of Compound 18 (20% in a 70:30 ethyl lactate: deionized water solution), and 0.60 g of PpTS solution (1% in PGME, Brewer Science, Inc.) were added. The contents were mixed for an hour prior to use and had 0.155% by weight solids. When spin-coated at 1,500 rpm for 60 seconds and baked 230° C. for 60 seconds, the film was recorded to be about 5 nm thick.

1. A method of forming a structure, said method comprising:
applying a composition to a stack so as to form an underlayer on the stack, said composition comprising a component dissolved or dispersed in a solvent system, said component:
being chosen from polymers, oligomers, monomers, or a combination thereof; and
comprising a cationic moiety comprising a ring chosen from heterocyclic rings, multi-heterocyclic rings, or combinations thereof, said ring comprising a positively charged nitrogen ring member, wherein when the ring is 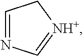
the anion is not 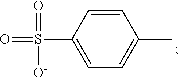
forming a photoresist layer on said underlayer; and
subjecting at least a portion of said photoresist layer to EUV radiation.

2. The method of claim 1, wherein said component is a polymer or oligomer comprising recurring monomers chosen from siloxanes, glycidyl-containing compounds, acrylates, methacrylates, 1-(3-sulfopropyl)-2-vinylpyridinium hydroxide, styrene, styrene-containing compounds, and combinations thereof.

3. The method of claim 1, wherein said ring can be substituted or unsubstituted and is chosen from imidazoles, pyridines, pyrimidines, pyrazines, pyridazines, purines, acridines, quinolines, isoquinolines, benzimidazoles, bi-pyridines, phenanthrenes, or combinations of the foregoing.

4. The method of claim 1, wherein said ring includes a carbon ring member bonded with a group chosen from substituted and unsubstituted alkyls, substituted and unsubstituted alkenyls, or combinations thereof.

5. The method of claim 1, further comprising an anion from a salt dispersed or dissolved in the solvent system.

6. The method of claim 1, further comprising an anion bound to said cationic moiety.

7. The method of claim 5, wherein said anion is chosen from halogen anions, sulfonate anions, phosphate anions, or combinations thereof.

8. The method of claim 5, wherein said anion is iodide.

9. The method of claim 1, said stack comprising:
a substrate having a surface; and
optionally one or more intermediate layers on said surface, there being an uppermost intermediate layer on said surface if one or more intermediate layers are present, said underlayer being on said uppermost intermediate layer, if present, or on said surface, if no intermediate layers are present.

10. The method of claim 1, further comprising:
forming a pattern in said photoresist layer after said subjecting said photoresist layer to EUV radiation; and
transferring said pattern:
to said underlayer;
to said intermediate layers, if present; and
to said substrate.

11. The method of claim 1, wherein said photoresist layer comprises a metal.

12. The method of claim 11, wherein said subjecting said photoresist layer to EUV radiation comprises using an exposure dose, and at least one of the following is true:
said exposure dose is about 5 mJ/cm² to about 80 mJ/cm²; or
said exposure dose is about 4 mJ/cm² or more below the exposure dose needed by a different layer that does not include said component but is otherwise chemically identical to said underlayer.

13. A structure comprising:
a substrate having a surface;
optionally one or more intermediate layers on said substrate surface, there being an uppermost intermediate layer on said substrate surface, if one or more intermediate layers are present;
an underlayer on said substrate surface, or on said uppermost intermediate layer, if present, said underlayer comprising an anion from a salt and a component chosen from polymers, oligomers, monomers, or a combination thereof, wherein:
said component comprises a cationic moiety comprising a ring chosen from heterocyclic rings, multi-heterocyclic rings, or combinations thereof, said ring comprising a positively charged nitrogen ring member; and
when the ring is 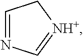
the anion is not 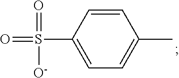
and
a photoresist on said underlayer.

14. The structure of claim 13, wherein said component comprises a crosslinked network, is bonded with said stack, or both.

15. The structure of claim 13, wherein said ring can be substituted or unsubstituted and is chosen from imidazoles, pyridines, pyrimidines, pyrazines, pyridazines, purines, acridines, quinolines, isoquinolines, benzimidazoles, bi-pyridines, phenanthrenes, or combinations of the foregoing.

16. The structure of claim 13, wherein said ring includes a carbon ring member bonded with a group chosen from substituted and unsubstituted alkyls, substituted and unsubstituted alkenyls, or combinations thereof.

17. The structure of claim 13, wherein said anion is bonded to said cationic moiety.

18. The structure of claim 13, wherein said anion is chosen from halogen anions, sulfonate anions, phosphate anions, or combinations thereof.

19. The structure of claim 18, wherein said anion is iodide.

20. The structure of claim 13, said stack comprising:
a substrate having a surface; and
optionally one or more intermediate layers on said surface, there being an uppermost intermediate layer on said surface if one or more intermediate layers are present, said underlayer being on said uppermost intermediate layer, if present, or on said surface, if no intermediate layers are present.

21. The structure of claim 13, wherein said photoresist layer comprises a metal.
